(19) United States
(12) Patent Application Publication
(10) Pub. No.: US 2024/0105635 A1
(43) Pub. Date: Mar. 28, 2024

(54) SELF-ALIGNMENT LAYER WITH LOW-K MATERIAL PROXIMATE TO VIAS

(71) Applicant: Intel Corporation, Santa Clara, CA (US)

(72) Inventors: Abhishek Anil Sharma, Portland, OR (US); Wilfred Gomes, Portland, OR (US); Tahir Ghani, Portland, OR (US); Anand Murthy, Portland, OR (US); Sagar Suthram, Portland, OR (US); Pushkar Ranade, San Jose, CA (US)

(73) Assignee: Intel Corporation, Santa Clara, CA (US)

(21) Appl. No.: 17/955,187

(22) Filed: Sep. 28, 2022

(51) Int. Cl. H01L 23/544; H01L 21/02; H01L 21/306; H01L 21/3205; H01L 23/48; H01L 23/532

(52) U.S. Cl. CPC H01L 23/544; H01L 21/0226; H01L 21/306; H01L 21/3205; H01L 23/481; H01L 23/5329

(57) ABSTRACT

An integrated circuit (IC) die includes a first layer with conductive structures formed in a interlayer dielectric (ILD) material, with a portion of the conductive structures at a first surface of the first layer, a self-alignment layer in contact with non-conductive regions at the first surface of the first layer, a second layer with ILD material in contact with the self-alignment layer and the portion of the conductive structures at the first surface of the first layer, and conductive vias through the self-alignment layer and the second layer in contact with the portion of the conductive structures at the first surface of the first layer. The self-alignment layer may include a first material where the self-alignment layer is in contact with the conductive vias and a second material where the self-alignment layer is not in contact with the conductive vias. Other embodiments are disclosed and claimed.

### BACKGROUND

There is an ongoing need for improved computational devices to enable ever increasing demand for modeling complex systems, providing reduced computation times, and other considerations. In some contexts, scaling features of integrated circuits has been a driving force for such improvements. Other advancements have been made in materials, device structure, circuit layout, and so on. In particular, there is an ongoing desire to improve via structures that are included in or otherwise support operation of integrated circuits. It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a cross-sectional side view of example integrated circuit (IC) die;

FIG. 2 illustrates a block diagram of an example of a system;

FIGS. 3A to 3D illustrate cross sectional side views of another example IC die at various process steps for in situ k value reduction;

FIGS. 4A to 4B illustrate cross sectional side views of another example IC die at various process steps for in situ k value reduction;

FIGS. 5A to 5C illustrate cross sectional side views of another example IC die at various process steps for in situ k value reduction;

FIGS. 6A to 6B illustrate cross sectional side views of another example IC die at various process steps for in situ k value reduction;

FIG. 7 illustrates a cross-sectional view of a low-temperature, k value reduction in self-aligned vias IC system using die- and package-level active cooling;

FIG. 8 illustrates a view of an example two-phase immersion cooling system for low-temperature operation of an IC die;

FIGS. 9A to 9B illustrates various processes or methods for forming self-aligned vias with k value reduction on an IC die;

FIG. 10 illustrates a diagram of an example data server machine employing an IC die with self-aligned vias with k value reduction; and

FIG. 11 is a block diagram of an example computing device, all in accordance with at least some implementations of the present disclosure.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve parasitics at a via level for a wide variety of via implementation techniques including, for example, single and dual damascene processes. Parasitics generally refer to physical effects caused by physical implementation of a circuit that may have a detrimental impact on circuit or signal behavior. Conventional techniques for self-alignment of vias may involve selective deposition of high k value material prior to via formation to aid in the via alignment. A problem is that high k value material in close proximity to the subsequently formed via may introduce higher parasitics. Some embodiments may overcome one or more of the foregoing problems. Some embodiments may utilize reduced or low k value material in a self-alignment layer where the material of the self-alignment layer comes in contact with vias.

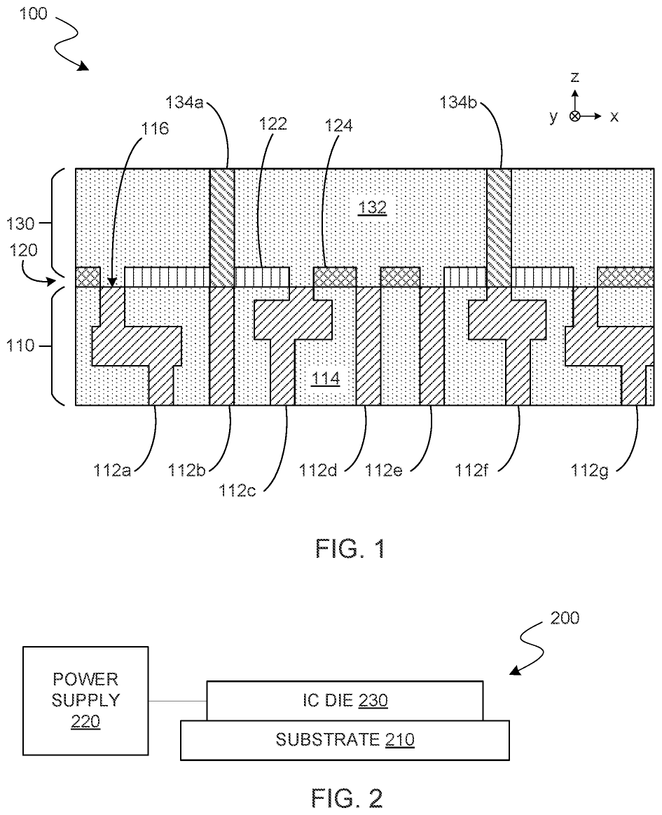

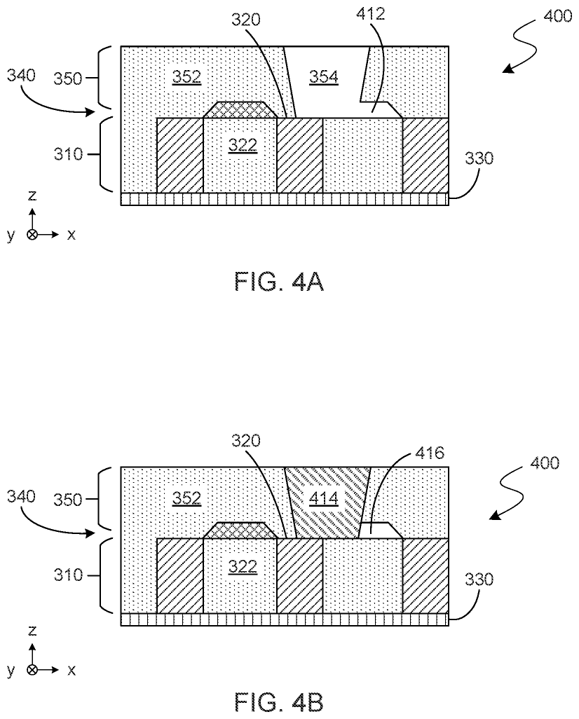

FIG. 1 shows an illustrative cross-sectional side view of an example integrated circuit (IC) 100 that includes self-aligned vias with reduced k values in accordance with some embodiments. The IC die 100 includes a first layer 110 with one or more conductive structures 112a-g (collectively, structures 112) formed in a first interlayer dielectric material 114, with at least a portion of the one or more conductive structures 112 at a first surface 116 of the first layer 110, a self-alignment layer 120 in contact with non-conductive regions at the first surface 116 of the first layer 110, a second layer 130 with second interlayer dielectric material 132 in contact with the self-alignment layer 120 and the portion of the one or more conductive structures 112 at the first surface 116 of the first layer 110, and one or more conductive vias 134a-b (collectively, vias 134) through the self-alignment layer 120 and the second layer 130 in respective contact with the portion of the one or more conductive structures 112 at the first surface 116 of the first layer 110. In some embodiments, the self-alignment layer 120 includes a first material 122 where the self-alignment layer 120 is in contact with the one or more conductive vias 134 and a second material 124 where the self-alignment layer 120 is not in contact with the one or more conductive vias 134 (e.g., indicated by different hatch patterns). For example, the first material 122 of the self-alignment layer 120 may comprise a low-k material and the second material 124 of the self-alignment layer 120 may comprise a high-k material. In some embodiments, a first dielectric constant of the first material 122 of the self-alignment layer 120 is less than a second dielectric constant of the second material 124 of the self-alignment layer 120. For example, the first dielectric constant may be three and nine tenths (3.9) or lower. In some implementations, the first material 122 may be air (e.g., with a dielectric constant of one (1.0)). In some implementations, the IC die may further comprise a non-conductive material in the second layer 130 between respective walls of the second interlayer dielectric material 132 and respective walls of the one or more conductive vias 134 (e.g., see FIG. 4C).

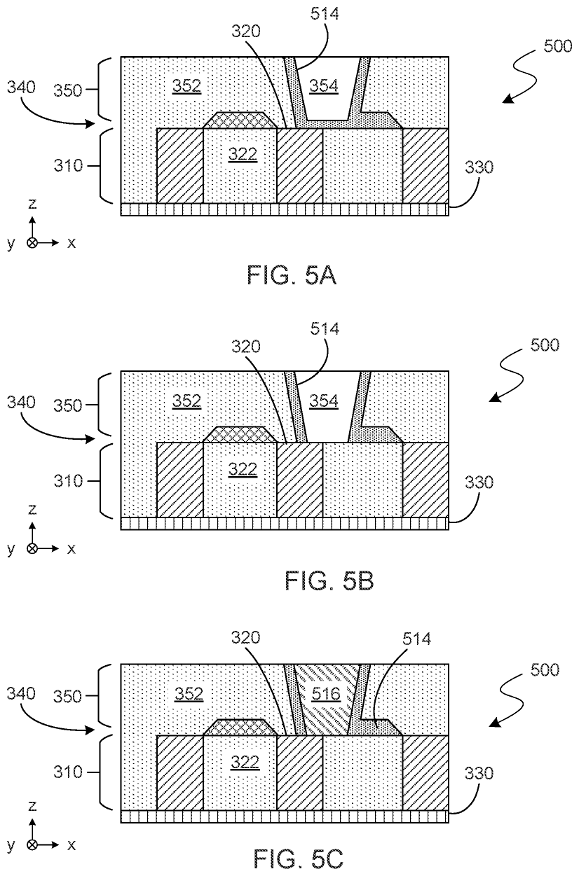

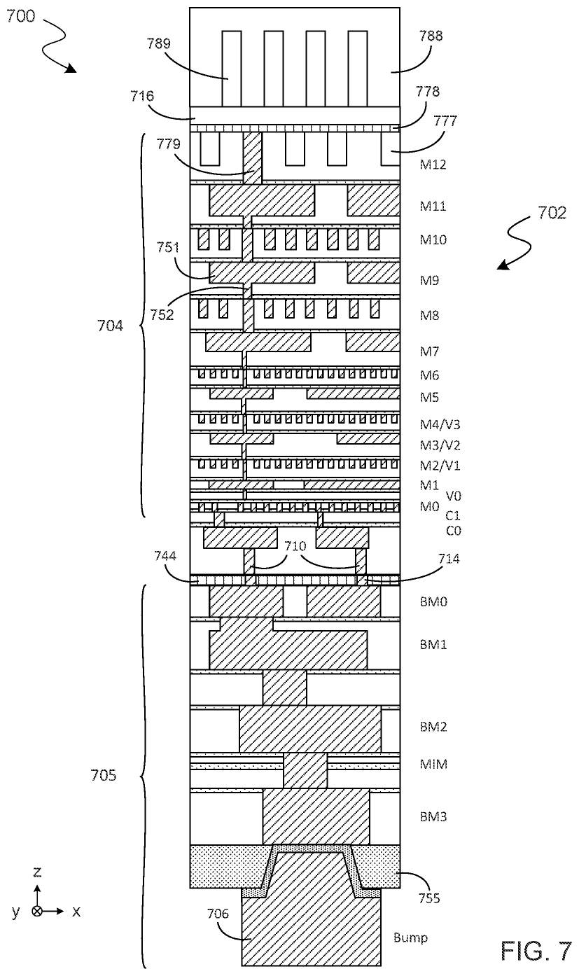

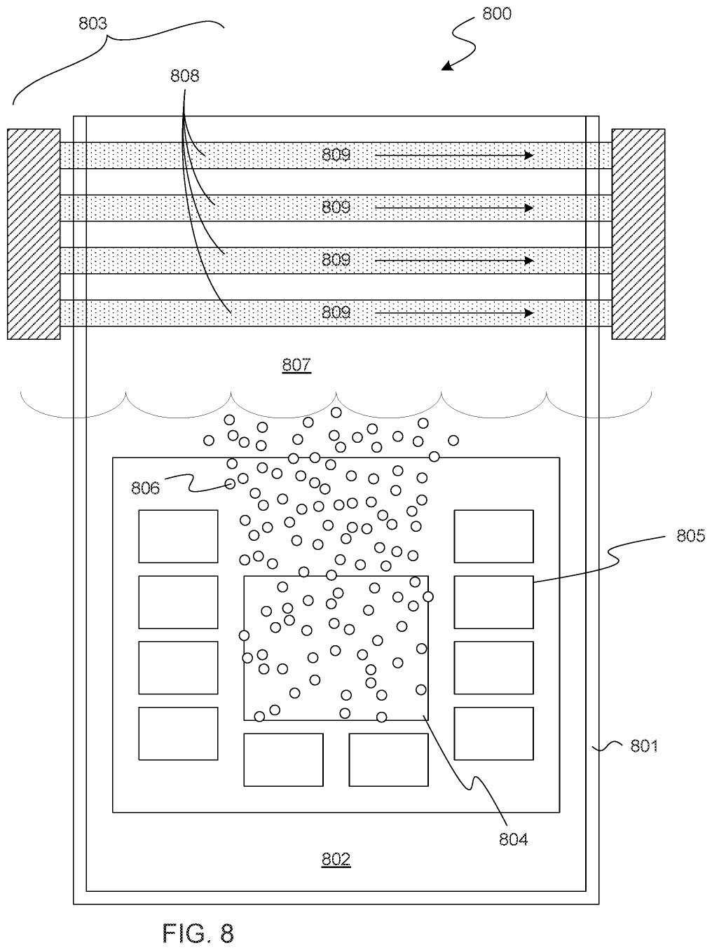

FIG. 2 shows a block diagram view of an example of a system 200 that includes a substrate 210, a power supply 220, and an IC die 230 attached to the substrate 210 and coupled to the power supply 220. The IC die 230 may be similarly configured as any of the various ICs described herein including, for example, the IC die 100 (FIG. 1), the IC die 400 (FIG. 4B), the IC die 500 (FIG. 5C), and IC die 702 (FIG. 7). Any suitable substrate technology may be utilized for the substrate 210 including, for example, the substrates described herein in connection with FIGS. 7 and 8 (e.g., substrate 805). In some embodiments, the IC die 230 may be coupled to the power supply 220 through the substrate 210.

Some embodiments may provide in situ k value reduction by using a replacement technology for self-aligned vias. In some embodiments, high k material used in a self-alignment layer that would come in contact with later formed vias is removed and replaced with a low k material in place of the high k material. Any suitable techniques may be utilized to replace the high k material with the low k material. FIGS. 2A to 6B show non-limiting example process steps that are suitable techniques for in situ k value reduction to replace high k value material with low k value material for self-aligned vias.

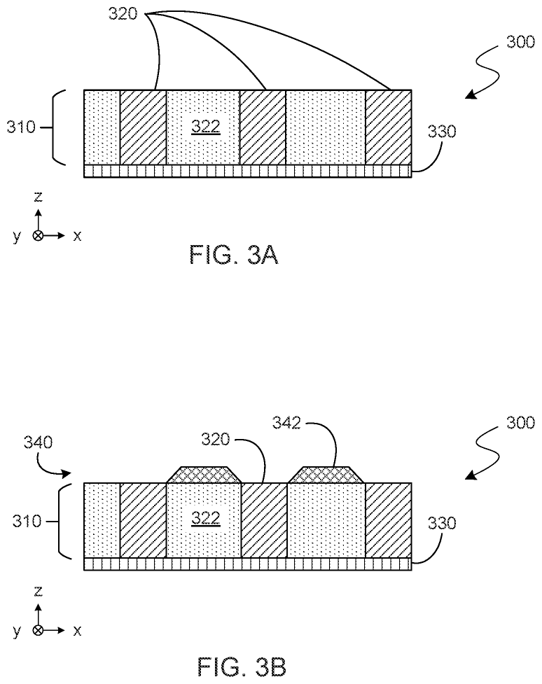

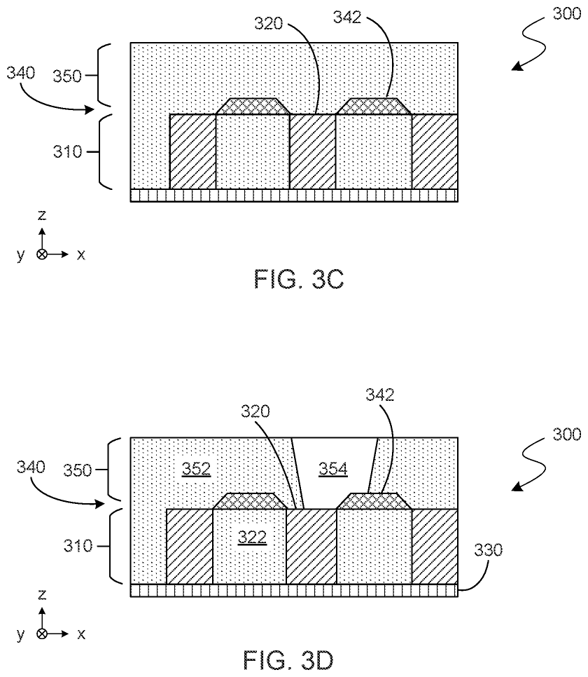

FIGS. 3A to 3D show illustrative cross sectional side views of an IC die 300 at various process steps. In FIG. 3A, a first layer 310 is formed with vias 320 (e.g., vertical metallization structures) formed through interlayer dielectric (ILD) material 322 to a substrate 330 of the IC die 300 (e.g., or to other preceding layers of the IC die 300). In FIG. 3B, a high-k self-alignment layer 340 is formed on the first layer 310. High-k material 342 of the self-alignment layer 340 nucleates only on oxides selectively, such that the material 342 only builds on top of the exposed oxides of the first layer and not the exposed metal of the vias 320. In FIG. 3C, a second layer 350 of ILD material 352 is deposited. In FIG. 3D, a hole 354 is formed in the ILD material 352. In some implementations of the process steps, the hole 354 may be well aligned (e.g., the hole 354 is substantially centered over the target contact on the first layer 310). But for most practical implementations, there may be some misalignment of the hole 354 with respect to the target contact.

For a conventional via formation process, metal may be deposited in the hole 354 for self-alignment of the via, and some metal material of the via may be in contact with the high-k material 342 of the self-alignment layer. In accordance with some embodiments, the high-k material 342 is replaced with low-k material prior to via formation. FIGS. 4A to 4B show one example of suitable process steps for in situ k value reduction to replace the high-k material 342 with low-k material for an IC die 400. After the process steps through FIG. 3D, in FIG. 4A, the high-k material 342 that is in communication with the hole 354 is removed, forming a recess 412. In FIG. 4B, metal 414 is deposited in the hole 354, forming an airgap 416 in the original place of the high-k material 342 at the recess 412. In the resulting IC die 400, the air in the airgap 416 provides in situ k value reduction with a low-k value with a dielectric constant of one (1.0).

Any suitable techniques may be utilized to remove the high-k material 342 and to deposit the metal 414. In some embodiments, a selective etch process may be utilized to selectively remove the high-k material 342. Any high-k material 342 exposed to the hole 354 is etched out. Advantageously, embodiments of a selective etch out of the self-alignment layer may improve parasitics by 15-20% at a via level in some implementations.

FIGS. 5A to 5C show another example of suitable process steps for in situ k value reduction to replace the high-k material 342 with low-k material for an IC die 500. After the process step shown in FIG. 4A (e.g., where the high-k material 342 that is in communication with the hole 354 is removed, forming the recess 412), in FIG. 5A a low-k ILD liner 514 is deposited. Any suitable technique may be utilized to the deposit the liner 514 including, for example, atomic layer deposition (ALD), chemical vapor deposition (CVD), physical vapor deposition (PVD), etc. The low-k ILD liner 514 may have a horizontal seam when ALD/CVD processes are used (e.g., the low-k liner 514 may be conformally grown such the middle of the low-k liner 514 may have a horizontal pinch-off). The low-k liner 514 covers the sidewalls of the hole 354 and also fills in the recess 412 that resulted from the removal of the high-k material 342. In FIG. 5B, a breakthrough etch is utilized to break through to the target contact of the first layer 310 (e.g., removing the bottom portion of the ILD liner 514). In FIG. 5C, metal 516 is deposited in the hole 354. In the resulting IC die 500, the low-k material 514 in place of the high-k material 342 provides in situ k value reduction with a low-k value with a dielectric constant of 3.9 or lower.

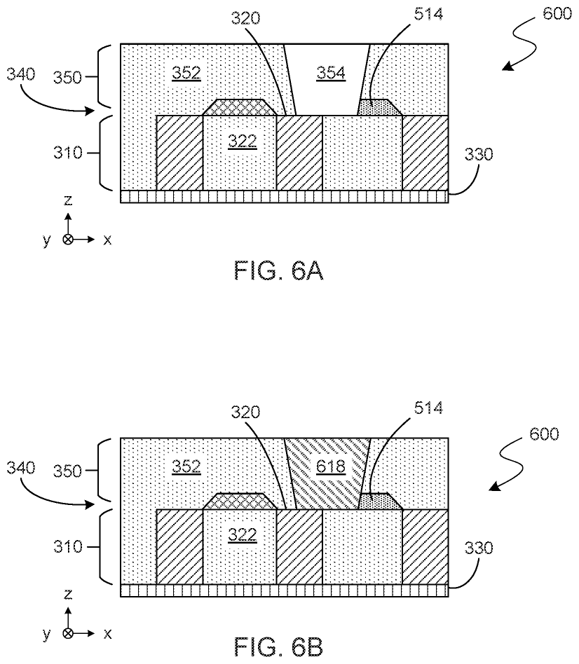

FIGS. 6A to 6B show another example of suitable process steps for in situ k value reduction to replace the high-k material 342 with low-k material for an IC die 600. After the process step shown in FIG. 5A or 5B (e.g., where the low-k material 514 is deposited), in FIG. 6A a sidewall etch is performed to remove the material 514 from the sidewalls of the hole 354 (e.g., and which may also result in removal of the material 514 from the bottom of the hole 354 if done prior to a breakthrough etch) while leaving the material 514 in the recess 412 that resulted from the removal of the high-k material 342. In FIG. 6B, metal 618 is deposited in the hole 354. In the resulting IC die 600, the low-k material 514 in place of the high-k material 342 provides in situ k value reduction with a low-k value with a dielectric constant of 3.9 or lower. As compared to the IC die 500, the metal 618 may have more contact area with the target contact on the first layer 310 because of the removal of the ILD liner material 514.

Some embodiments may involve a seam while other embodiments may be considered seamless. Generally, techniques that utilize ALD or CVD will likely involve some form of seam. Techniques that involve material growth may be considered seamless. In some embodiments, a seam may be removed by transforming the material (e.g., exposing the material to an oxygen anneal or oxygen plasma). For example, tungsten metal that is deposited by ALD may subsequently be oxidized to remove the seam.

In some embodiments, ICs with k value reduction in self-aligned vias may be integrated into a low-temperature system. Lower temperatures enhance conduction in many materials and can enable the use of, e.g., different materials and structures (such as smaller transistor channels). A number of structures may be used to lower the system temperature and so allow for the use of, e.g., smaller conducting structures. Active cooling structures can be used to lower system temperatures to below ambient temperature, even to well below ambient temperature. Active cooling structures can include thermoelectric coolers. In some embodiments, active cooling structures include stacks of alternating p- and n-type semiconductor materials. In some embodiments, active cooling structures flow cooling fluids through channels, including microchannels, thermally coupled to IC packages. In some embodiments, active cooling structures include channels thermally coupled to IC dies 100. In some embodiments, active cooling structures include channels on one or more sides of IC dies 100. In some embodiments, active cooling structures include channels within IC dies 100. In some embodiments, active cooling structures include two-phase cooling. In some embodiments, active cooling structures include low-boiling-point fluids. In some embodiments, active cooling structures include refrigerants as cooling fluids. In some embodiments, active cooling structures lower system temperatures to below 0° C.

Embodiments that deposit a liner to fill the recess that results from the removal of the high-k material of the self-alignment layers may be particularly applicable for low-temperature systems. In some embodiments (e.g., the IC die 500), the via size shrinks due to the ILD liner. At room temperature, the potential misalignment and smaller via size may result in extra interface resistance that may negatively impact performance. At low-temperature, however, the metal resistance is less impactful and performance may not be negatively impacted. Accordingly, for low-temperature systems, the IC die 500 may be preferred because the k value reduction for self-aligned vias provides benefits of lower capacitance while keeping the resistance low (e.g., without negatively affecting the performance of the system), and keeping the ILD liner saves a process step which advantageously reduces cost.

FIG. 7 illustrates a cross-sectional view of a low-temperature IC system 700 using die- and package-level active cooling, that further includes self-aligned vias with k value reduction, in accordance with some embodiments. In the example of IC system 700, IC die 702 includes active-cooling structures or components as provided by both die-level microchannels 777 and package-level active-cooling structure 788. IC system 700 includes a lateral surface along the x-y plane that may be defined or taken at any vertical position of IC system 700. The lateral surface of the x-y plane is orthogonal to a vertical or build-up dimension as defined by the z-axis. In some embodiments, IC system 700 may be formed from any substrate material suitable for the fabrication of transistor circuitry. In some embodiments, a semiconductor substrate is used to manufacture self-aligned vias with k value reduction and other transistors and components of IC system 700. The semiconductor substrate may include a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In FIG. 7, IC system 700 includes an IC die 702, which is a monolithic IC with k value reduction in self-aligned vias as described herein, including front-side metallization layers 704 (or front-side interconnect layers), and optional back-side metallization layers 705 (or back-side interconnect layers). As shown, IC die 702 may include vias 710 embedded within a dielectric layer. Each of the vias 710 contact only low-k material of a self-alignment layer where the self-alignment layer is in contact with the vias 710. The self-alignment layer further includes high-k material where the vias 710 are not in contact in the self-alignment layer (the detailed structure of the low-k and high-k materials of the self-alignment layer is omitted from the cross-section of FIG. 7 to avoid obscuring the figure). In some embodiments, front-side metallization layers 704 (that may also include self-aligned vias with k value reduction) provide signal routing to the non-planar transistors and back-side metallization layers 705 (that may also include self-aligned vias with k value reduction) provide power delivery, as enabled by vias 710 (e.g., and through-contacts 714). In some embodiments, the package-level cooling structure 788 may be deployed on or over front-side metallization layers 704 (as shown) or on or over a back-side of IC die 702. In some embodiments, package-level cooling structure 788 is coupled to IC die 702 by an adhesion layer 716. IC system 700 may also be deployed without back-side metallization layers 705 shown in FIG. 7. In such embodiments, signal routing and power are provided to circuits of the IC die 702 via front-side metallization layers 704. However, use of back-side metallization layers 705 may offer advantages.

The circuits of the IC die 702 are connected and thermally coupled by metallization, e.g., metal heat spreader 744, to the entire metallization structure by through-contacts 714. In this way, circuits of the IC die 702 are thermally coupled to both the die-level active-cooling structures (of die-level microchannels 777) and package-level active-cooling structure 788.

Interconnectivity of transistors, signal routing to and from circuitry of the IC die 702, vias 710 (e.g., and other vias), etc., power delivery to circuitry of the IC die 702, etc., and routing to an outside device (not shown), is provided by front-side metallization layers 704, optional back-side metallization layers 705, and package-level interconnects 706. In the example of FIG. 7, package-level interconnects 706 are provided on or over a back-side of IC die 702 as bumps over a passivation layer 755, and IC system 700 is attached to a substrate (and coupled to signal routing to, power delivery, etc.) by package-level interconnects 706. However, package-level interconnects 706 may be provided using any suitable interconnect structures such as bond pads, solder bumps, etc. Furthermore, in some embodiments, package-level interconnects 706 are provided on or over a front-side of IC die 702 (i.e., over front-side metallization layers 704) and package-level cooling structure 788 is provided on or over a back-side of IC die 702.

In IC system 700, IC die 702 includes die-level, active-cooling as provided by die-level microchannels 777. Die-level microchannels 777 are to convey a heat transfer fluid therein to remove heat from IC die 702. The heat transfer fluid may be any suitable liquid or gas. In some embodiments, the heat transfer fluid is liquid nitrogen operable to lower the temperature of IC die 702 to a temperature at or below about −196° C. In some embodiments, the heat transfer fluid is a fluid with a cryogenic temperature operating window (e.g., about −180° C. to about −70° C.). In some embodiments, the heat transfer fluid is one of helium-3, helium-4, hydrogen, neon, air, fluorine, argon, oxygen, or methane.

As used herein, the term “microchannels” indicates a channel to convey a heat transfer fluid with the multiple microchannels providing discrete separate channels or a network of channels. Notably, the plural microchannels does not indicate separate channel networks are needed. Such die-level microchannels 777 may be provided in any pattern in the x-y plane such as serpentine patterns, patterns of multiple parallel die-level microchannels 777, or the like. Die-level microchannels 777 couple to a heat exchanger (not shown) that removes heat from and cools the heat transfer fluid before re-introduction to die-level microchannels 777. The flow of fluid within die-level microchannels 777 may be provided by a pump or other fluid flow device. The operation of the heat exchanger, pump, etc. may be controlled by a controller.

In the illustrated embodiment, die-level microchannels 777 are implemented at metallization level M12. In other embodiments, die-level microchannels 777 are implemented over metallization level M12. Die-level microchannels 777 may be formed using any suitable technique or techniques such as patterning and etch techniques to form the void structures of die-level microchannels 777 and passivation or deposition techniques to form a cover structure 778 to enclose the void structures. As shown, in some embodiments, the die-level, active-cooling structure of IC system 700 includes a number of die-level microchannels 777 in IC die 702 and over a number of front-side metallization layers 704. As discussed, die-level microchannels 777 are to convey a heat transfer fluid therein. In some embodiments, a metallization feature 779 of metallization layer M12 is laterally adjacent to die-level microchannels 777. For example, metallization feature 779 may couple to a package-level interconnect structure (not shown) for signal routing for IC die 702. In some embodiments, a passive heat removal device such as a heat sink or the like may be used instead of or in addition to package-level cooling structure 788. In some embodiments, package-level cooling structure 788 is not deployed in IC system 700.

As used herein, the term “metallization layer” describes layers with interconnections or wires that provide electrical routing, generally formed of metal or other electrically and thermally conductive material. Adjacent metallization layers may be formed of different materials and by different methods. Adjacent metallization layers, such as metallization interconnects 751, are interconnected by vias, such as vias 752 (e.g., that may self-aligned vias with k value reduction as described herein), that may be characterized as part of the metallization layers or between the metallization layers. As shown, in some embodiments, front-side metallization layers 704 are formed over and immediately adjacent transistors. The back-side is then the opposite side, which may be exposed during processing by attaching the front-side to a carrier wafer and exposing the back-side (e.g., by back-side grind or etch operations) as known in the art.

In the illustrated example, front-side metallization layers 704 include M0, V0, M1, M2/V1, M3/V2, M4/V3, and M4-M12. However, front-side metallization layers 704 may include any number of metallization layers such as eight or more metallization layers. Similarly, back-side metallization layers 705 include BM0, BM1, BM2, and BM3. However, back-side metallization layers 705 may include any number of metallization layers such as two to five metallization layers. Front-side metallization layers 704 and back-side metallization layers 705 are embedded within dielectric materials. Furthermore, optional metal-insulator-metal (MIM) devices such as diode devices may be provided within back-side metallization layers 705. Other devices such as capacitive memory devices may be provided within front-side metallization layers 704 and/or back-side metallization layers 705.

IC system 700 includes package-level active-cooling structure 788 having package-level microchannels 789. Package-level microchannels 789 are to convey a heat transfer fluid therein to remove heat from IC die 702. The heat transfer fluid may be any suitable liquid or gas as discussed with respect to die-level microchannels 777. Package-level microchannels 789 may be provided in any pattern in the x-y plane such as serpentine patterns, patterns of multiple parallel package-level microchannels 789, etc. Package-level microchannels 789 couple to a heat exchanger (not shown) that removes heat from and cools the heat transfer fluid before re-introduction to package-level microchannels 789. The flow of fluid within package-level microchannels 789 may be provided by a pump or other fluid-flow device. The operation of the heat exchanger, pump, etc. may be controlled by a controller. In the illustrated embodiment, package-level active-cooling structure 788 is a chiller mounted to IC die 702 such that the chiller has a solid body having microchannels therein to convey a heat transfer fluid.

In some embodiments, the heat-removal fluid deployed in die-level microchannels 777 and package-level active-cooling structure 788 are coupled to the same pump and heat exchanger systems. In such embodiments, the heat removal fluid conveyed in both die-level microchannels 777 and package-level active-cooling structure 788 are the same material. Such embodiments may advantageously provide simplicity. In other embodiments, the heat removal fluids are controlled separately. In such embodiments, the heat removal fluids conveyed by die-level microchannels 777 and package-level active-cooling structure 788 may be the same or they may be different. Such embodiments may advantageously provide improved flexibility.

As discussed, IC system 700 includes IC die 702 and optional die-level and package-level active-cooling structures operable to remove heat from IC die 702 to achieve a very low operating temperature of IC die 702. As used herein, the term “very low operating temperature” indicates a temperature at or below 0° C., although even lower temperatures such as an operating temperature at or below −50° C., an operating temperature at or below −70° C., an operating temperature at or below −100° C., an operating temperature at or below −180° C., or an operating temperature at or below −196° C. may be used. In some embodiments, the operating temperature is in a cryogenic temperature operating window (e.g., about −180° C. to about −70° C.). The active-cooling structure may be provided as a package-level structure (i.e., separable from IC die 702), as a die-level structure (i.e., integral to IC die 702), or both. In some embodiments, IC die 702 is deployed in a cold environment, formed using sufficiently conductive materials, etc. and an active-cooling structure is not used.

FIG. 8 illustrates a view of an example two-phase immersion cooling system 800 for low-temperature operation of an IC die, in accordance with some embodiments. As shown, two-phase immersion cooling system 800 includes a fluid containment structure 801, a low-boiling point liquid 802 within fluid containment structure 801, and a condensation structure 803 at least partially within fluid containment structure 801. As used herein, the term “low-boiling point liquid” indicates a liquid having a boiling point in the very low temperature ranges discussed. In some embodiments, the low-boiling point liquid is one of helium-3, helium-4, hydrogen, neon, air, fluorine, argon, oxygen, or methane.

In operation, a heat generation source 804, such as an IC package including any of IC dies or systems 100, 200, 300, 400, 500, 600, 700 as discussed herein is immersed in low-boiling point liquid 802. In some embodiments, IC dies or systems 100, 200, 300, 400, 500, 600, 700 as deployed in two-phase immersion cooling system 800 do not include additional active cooling structures, although such die-level or package-level active cooling structures may be used in concert with two-phase immersion cooling system 800. In some embodiments, when deployed in two-phase immersion cooling system 800, package-level active-cooling structure 788 is a heat sink, a heat dissipation plate, a porous heat dissipation plate or the like.

Notably, IC die 702 (or IC die 100, 200, 300, 400, 500, 600), is the source of heat in the context of two-phase immersion cooling system 800. For example, IC die 702 may be packaged and mounted on electronics substrate 805. Electronic substrate 805 may be coupled to a power supply (not shown) and may be partially or completely submerged in low-boiling point liquid 802.

In operation, the heat produced by heat generation source 804 vaporizes low-boiling point liquid 802 as shown in vapor or gas state as bubbles 806, which may collect, due to gravitational forces, above low-boiling point liquid 802 as a vapor portion 807 within fluid containment structure 801. Condensation structure 803 may extend through vapor portion 807. In some embodiments, condensation structure 803 is a heat exchanger having a number of tubes 808 with a cooling fluid (i.e., a fluid colder than the condensation point of vapor portion 807) shown by arrows 809 that may flow through tubes 808 to condense vapor portion 807 back to low-boiling point liquid 802. In the IC system of FIG. 8, package-level active-cooling structure 788 includes a passive cooling structure such as a heat sink for immersion in low-boiling point liquid 802.

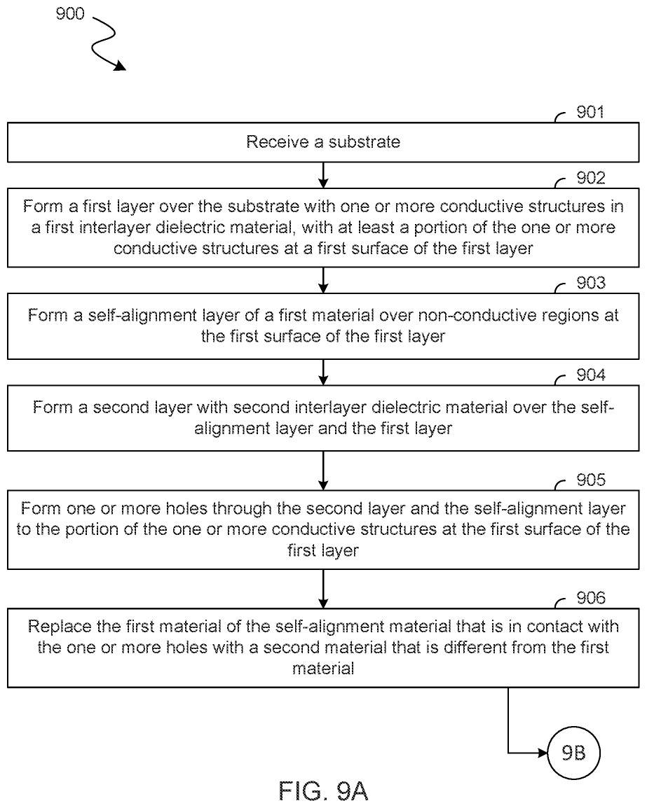

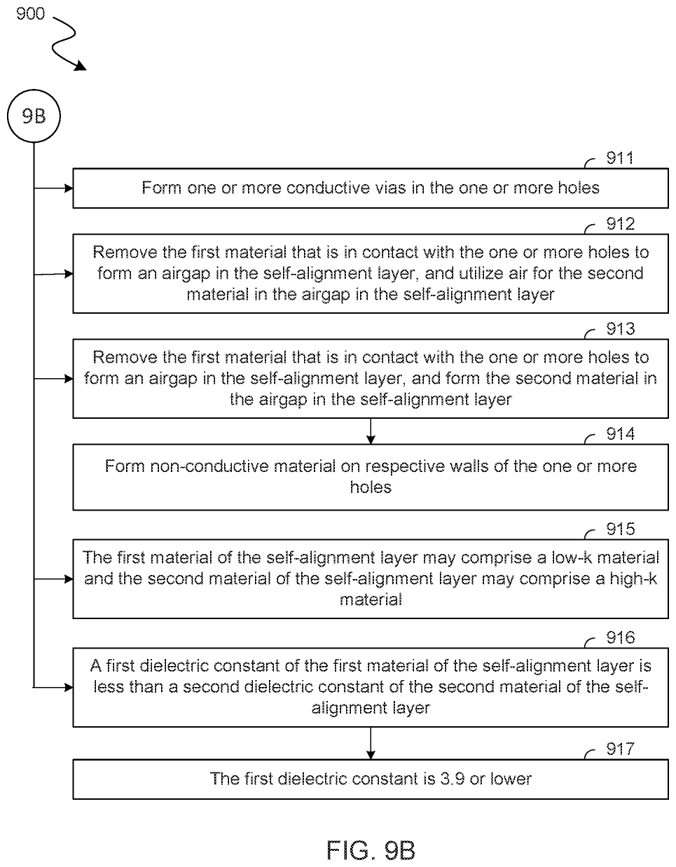

FIGS. 9A to 9B illustrate various processes or methods 900 for forming self-aligned vias with k value reduction on an IC die, in accordance with some embodiments. FIGS. 9A to 9B show methods 900 that includes operations 901-917. Some operations shown in FIGS. 9A to 9B are optional. FIGS. 9A to 9B show an example sequence, but the operations can be done in other sequences as well, and some operations may be omitted. Some operations can also be performed multiple times before other operations are performed. Some operations may be included within other operations. Methods 900 generally entail forming self-aligned vias and replacing self-alignment layer high-k value material with low-k value material where the self-alignment layer material contacts the self-aligned vias.

In operation 901, a substrate is received. The substrate is a planar platform and may already include dielectric and metallization structures. The substrate may be one of many layers in an IC die, and may itself have many layers. The substrate may be above other layers in the IC die (all or of a portion of which may be subsequently removed in back-side metallization contexts), and other layers may subsequently be formed in or over the substrate. In some embodiments, self-aligned vias with k value reduction will be formed on a frontside of the substrate. In some embodiments, self-aligned vias with k value reduction will be formed on a backside. In some embodiments, self-aligned vias with k value reduction will be formed on both sides.

The substrate may include any suitable material or materials. Any suitable semiconductor or other material can be used. Transistors in the IC die may be of the same material as the substrate or, e.g., deposited on the substrate. The substrate may include a semiconductor material that transistors can be formed out of and on, including a crystalline material. In some examples, the substrate may include monocrystalline silicon (Si), germanium (Ge), silicon germanium (SiGe), a III-V alloy material (e.g., gallium arsenide (GaAs)), a silicon carbide (SiC), a sapphire (Al2O3), or any combination thereof. In some embodiments, the substrate includes crystalline silicon and subsequent components are also silicon.

In operation 902, a first layer is formed over the substrate with one or more conductive structures in a first interlayer dielectric material, with at least a portion of the one or more conductive structures at a first surface of the first layer. The first layer need not be formed before, e.g., other layers of the IC die. Forming the first layer and other layers of the IC die may include forming transistors, resistors, and interconnections, e.g., between them and with external structures, including power, signal, data, ground, etc. lines. At least some of these structures may be conventional and known methods may be used.

Transistors in the first layer can be formed from the same material as the substrate or, e.g., deposited on the substrate. In some embodiments, the substrate is crystalline silicon and transistors in the first layer are formed by etching back the substrate to form transistor structures, e.g., non-planar structures, such as fins for access transistor channels. In some embodiments, transistors comprise polycrystalline silicon, which may be deposited over other materials. Other semiconductor materials may be deposited as well, on the substrate or over other structures on the substrate. Such semiconductor materials can be any material suitable for forming a transistor channel, e.g., for an access transistor, but some materials will be preferred for their manufacturing properties, e.g., the capability to be deposited easily, in a well-controlled manner, and in thin layers.

Forming the first layer may include forming ultrathin structures, such as nanowires, nanoribbons, or nanosheets, for transistor channels. In some embodiments, one or a few monolayers of semiconductor materials are deposited over the substrate or other structures. In some embodiments, less than 2 nm of semiconductor material is deposited as a film. In some embodiments, a transition-metal dichalcogenide (TMD) material is deposited to form access transistors. TMDs can be 2D materials, e.g., forming monolayers of semiconductor materials. 2D materials may be deposited on structures, such as backbone features, deposited on the substrate.

The methods for forming transistors may vary with transistor function. TFTs for use as pull-up transistors may be formed as parasitic devices deposited over other structures in some layers. In some embodiments, forming transistors includes depositing amorphous or polycrystalline metal oxides. In some embodiments, a thin, metal-oxide film is deposited that may be semiconducting substantially as-deposited, and/or following some subsequent activation process, such as a thermal anneal.

Other structures, e.g., resistors and metallization, may also be deposited or otherwise formed from such materials, and such forming may be done throughout the forming operations of transistors and other structures. Pull-up resistors may be formed from the substrate material or, e.g., by depositing polycrystalline silicon or other material over the substrate. Other structures, e.g., access transistor gate electrodes, may be formed such that convenient connections can be made to associated structures in the first layer. Metallization may be formed before and after, and interleaved throughout, the forming of other structures.

In operation 903, a self-alignment layer of a first material is formed over non-conductive regions at the first surface of the first layer.

The self-alignment layer is formed in or on the substrate and in a layer vertically adjacent the first layer. The self-alignment layer may be formed after the first layer. Structures in the self-alignment layer may be deposited or grown over the top of the first layer. Structures formed, e.g., etched, from a front side of the substrate in the first layer may be formed, e.g., etched, from a back side of the substrate in another layer. Layouts may be duplicated or mirrored as suits an embodiment.

In operation 904, a second layer with second interlayer dielectric material is formed over the self-alignment layer and the first layer. The second layer is formed in or on the substrate and in a layer vertically adjacent the self-alignment layer and the first layer. The second layer may be formed after the first layer, above the first layer. The second layer may be formed in a similar manner as the first layer. Deposited structures in the second layer may be deposited over the top of the first layer, e.g., after an insulating layer is formed over the first layer. Structures formed, e.g., etched, from a front side of the substrate in the second layer may be formed, e.g., etched, from a back side of the substrate in another layer. Layouts may be duplicated or mirrored as suits an embodiment.

In operation 905, one or more holes are formed through the second layer and the self-alignment layer to the portion of the one or more conductive structures at the first surface of the first layer. In operation 906, the first material of the self-alignment material that is in contact with the one or more holes is replaced with a second material that is different from the first material.

In operation 911, one or more conductive vias are formed in the one or more holes. Following this operation, the first and second layers are electrically connected. In some embodiments, two circuits or signals (and more) are formed in vertically adjacent layers where in different metallization layers are connected between layers by forming a vertical metallization structure, e.g., a metallized via connection, on one side of the layers, beyond the horizontal edges or boundaries of the circuits. In some such embodiments, a deep border via connects the different metallization layers. In some embodiments, two of these connected circuits are vertically aligned, and other connected circuits in both layers are not vertically aligned. The vertical metallization structure, e.g., a via, can be formed as part of traditional or other methods, e.g. single or dual damascene techniques, etc.

In operation 912, replacing the first material further comprises removing the first material that is in contact with the one or more holes to form an airgap in the self-alignment layer, and utilizing air for the second material in the airgap in the self-alignment layer.

In operation 913, replacing the first material further comprises removing the first material that is in contact with the one or more holes to form an airgap in the self-alignment layer; and forming the second material in the airgap in the self-alignment layer. In operation 914, non-conductive material is formed on respective walls of the one or more holes.

At box 915, the first material of the self-alignment layer may comprise a low-k material and the second material of the self-alignment layer may comprise a high-k material. At box 916, a first dielectric constant of the first material of the self-alignment layer is less than a second dielectric constant of the second material of the self-alignment layer. For example, at box 917, the first dielectric constant is 3.9 or lower.

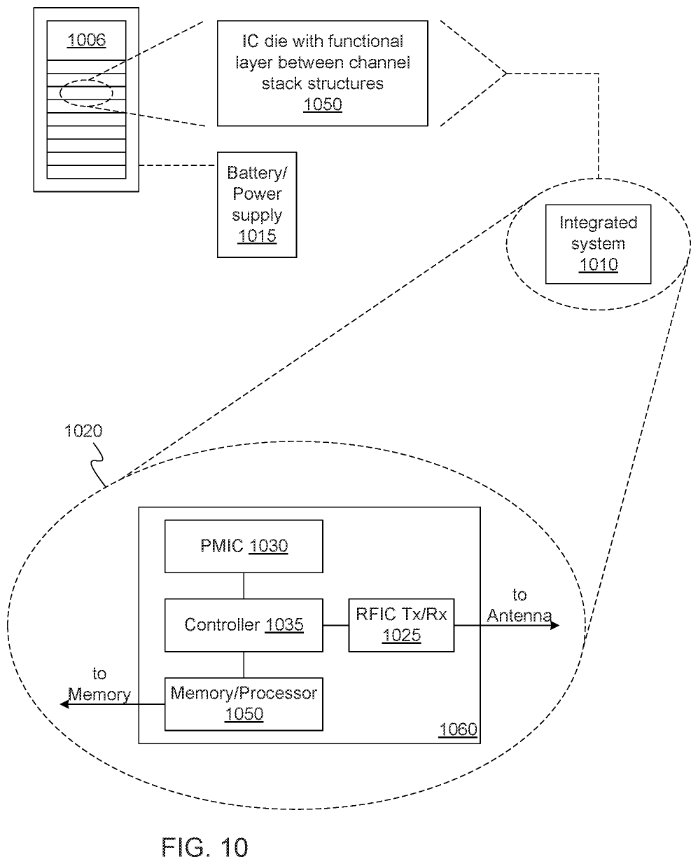

FIG. 10 illustrates a diagram of an example data server machine 1006 employing an IC die with self-aligned vias with k value reduction, in accordance with some embodiments. Server machine 1006 may be any commercial server, for example, including any number of high-performance computing platforms disposed within a rack and networked together for electronic data processing, which in the exemplary embodiment includes one or more devices 1050 having self-aligned vias with k value reduction.

Also as shown, server machine 1006 includes a battery and/or power supply 1015 to provide power to devices 1050, and to provide, in some embodiments, power delivery functions such as power regulation. Devices 1050 may be deployed as part of a package-level integrated system 1010. Integrated system 1010 is further illustrated in the expanded view 1020. In the exemplary embodiment, devices 1050 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 1050 is a microprocessor including a cache memory. As shown, device 1050 may be a multi-chip module employing one or more IC dies with self-aligned vias with k value reduction, as discussed herein. Device 1050 may be further coupled to (e.g., communicatively coupled to) a board, an interposer, or a substrate 1060 along with, one or more of a power management IC (PMIC) 1030, RF (wireless) IC (RFIC) 1025, including a wideband RF (wireless) transmitter and/or receiver (TX/RX) (e.g., including a digital baseband and an analog front end module further comprises a power amplifier on a transmit path and a low noise amplifier on a receive path), and a controller 1035 thereof. In some embodiments, RFIC 1025, PMIC 1030, controller 1035, and device 1050 include IC dies having with self-aligned vias with k value reduction on substrate 1060 in a multi-chip module.

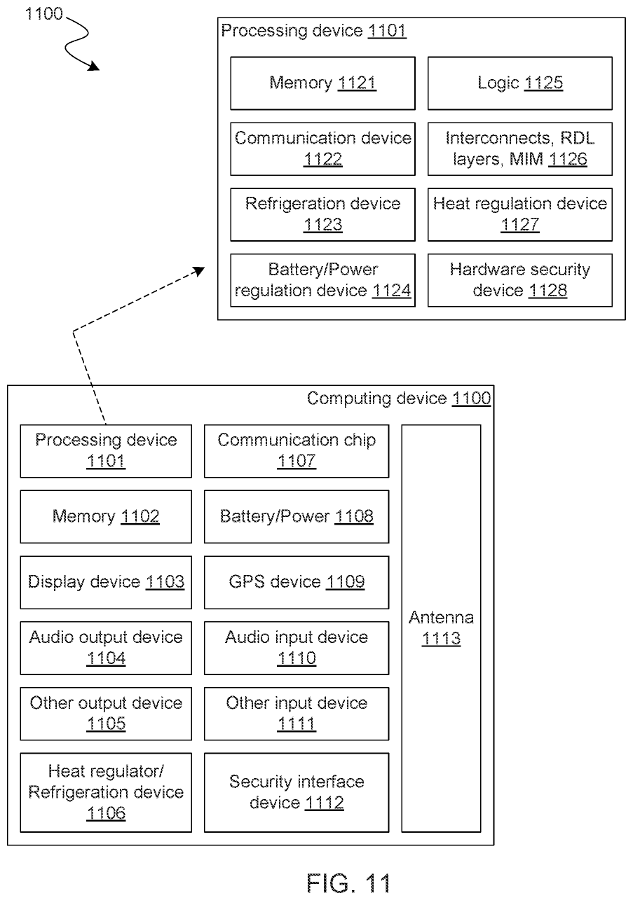

FIG. 11 is a block diagram of an example computing device 1100, in accordance with some embodiments. For example, one or more components of computing device 1100 may include any of the devices or structures discussed herein. A number of components are illustrated in FIG. 11 as being included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121 (itself including self-aligned vias with k value reduction), a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1102 includes memory that shares a die with processing device 1101. This memory may be used as cache memory and may include embedded dynamic random-access memory (eDRAM) or spin transfer torque magnetic random-access memory (STT-M RAM).

Computing device 1100 may include a heat regulation/refrigeration device 1106. Heat regulation/refrigeration device 1106 may maintain processing device 1101 (and/or other components of computing device 1100) at a predetermined low temperature during operation. This predetermined low temperature may be any temperature discussed herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an antenna 1113 to facilitate wireless communications and/or to receive other wireless communications (such as AM or FM radio transmissions).

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-11. The subject matter may be applied to other deposition applications, as well as any appropriate manufacturing application, as will be understood to those skilled in the art.

The following examples pertain to further embodiments, and specifics in the examples may be used anywhere in one or more embodiments.

Example 1 includes an integrated circuit (IC) die, comprising a first layer with one or more conductive structures formed in a first interlayer dielectric material, with at least a portion of the one or more conductive structures at a first surface of the first layer, a self-alignment layer in contact with non-conductive regions at the first surface of the first layer, a second layer with second interlayer dielectric material in contact with the self-alignment layer and the portion of the one or more conductive structures at the first surface of the first layer, and one or more conductive vias through the self-alignment layer and the second layer in respective contact with the portion of the one or more conductive structures at the first surface of the first layer, wherein the self-alignment layer includes a first material where the self-alignment layer is in contact with the one or more conductive vias and a second material where the self-alignment layer is not in contact with the one or more conductive vias.

Example 2 includes the IC die of Example 1, wherein the first material of the self-alignment layer comprises a low-k material and the second material of the self-alignment layer comprises a high-k material.

Example 3 includes the IC die of any of Examples 1 to 2, wherein a first dielectric constant of the first material of the self-alignment layer is less than a second dielectric constant of the second material of the self-alignment layer.

Example 4 includes the IC die of Example 3, wherein the first dielectric constant is 3.9 or lower.

Example 5 includes the IC die of Example 4, wherein the first material is air.

Example 6 includes the IC die of any of Examples 1 to 5, further comprising a non-conductive material in the second layer between respective walls of the second interlayer dielectric material and respective walls of the one or more conductive vias.

Example 7 includes a system, comprising a substrate, a power supply, and an integrated circuit (IC) die attached to the substrate and coupled to the power supply, the IC die comprising a first layer with one or more conductive structures formed in a first interlayer dielectric material, with at least a portion of the one or more conductive structures at a first surface of the first layer, a self-alignment layer in contact with non-conductive regions at the first surface of the first layer, a second layer with second interlayer dielectric material in contact with the self-alignment layer and the portion of the one or more conductive structures at the first surface of the first layer, and one or more conductive vias through the self-alignment layer and the second layer in respective contact with the portion of the one or more conductive structures at the first surface of the first layer, wherein the self-alignment layer includes a first material where the self-alignment layer is in contact with the one or more conductive vias and a second material where the self-alignment layer is not in contact with the one or more conductive vias.

Example 8 includes the system of Example 7, wherein the first material of the self-alignment layer comprises a low-k material and the second material of the self-alignment layer comprises a high-k material.

Example 9 includes the system of any of Examples 7 to 8, wherein a first dielectric constant of the first material of the self-alignment layer is less than a second dielectric constant of the second material of the self-alignment layer.

Example 10 includes the system of Example 9, wherein the first dielectric constant is 3.9 or lower.

Example 11 The system of Example 10, wherein the first material is air.

Example 12 includes the system of any of Examples 7 to 11, further comprising a non-conductive material in the second layer between respective walls of the second interlayer dielectric material and respective walls of the one or more conductive vias.

Example 13 includes a method, comprising receiving a substrate, forming a first layer over the substrate with one or more conductive structures in a first interlayer dielectric material, with at least a portion of the one or more conductive structures at a first surface of the first layer, forming a self-alignment layer of a first material over non-conductive regions at the first surface of the first layer, forming a second layer with second interlayer dielectric material over the self-alignment layer and the first layer, forming one or more holes through the second layer and the self-alignment layer to the portion of the one or more conductive structures at the first surface of the first layer, and replacing the first material of the self-alignment material that is in contact with the one or more holes with a second material that is different from the first material.

Example 14 includes the method of Example 13, further comprising forming one or more conductive vias in the one or more holes.

Example 15 includes the method of any of Examples 13 to 14, wherein replacing the first material further comprises removing the first material that is in contact with the one or more holes to form an airgap in the self-alignment layer, and utilizing air for the second material in the airgap in the self-alignment layer.

Example 16 includes the method of any of Examples 13 to 14, wherein replacing the first material further comprises removing the first material that is in contact with the one or more holes to form an airgap in the self-alignment layer, and forming the second material in the airgap in the self-alignment layer.

Example 17 includes the method of Example 16, further comprising forming non-conductive material on respective walls of the one or more holes.

Example 18 includes the method of any of Examples 13 to 17, wherein the first material of the self-alignment layer comprises a low-k material and the second material of the self-alignment layer comprises a high-k material.

Example 19 includes the method of any of Examples 13 to 18, wherein a first dielectric constant of the first material of the self-alignment layer is less than a second dielectric constant of the second material of the self-alignment layer.

Example 20 includes the method of Example 19, wherein the first dielectric constant is 3.9 or lower.

Example 21 includes an apparatus, comprising means for receiving a substrate, means for forming a first layer over the substrate with one or more conductive structures in a first interlayer dielectric material, with at least a portion of the one or more conductive structures at a first surface of the first layer, means for forming a self-alignment layer of a first material over non-conductive regions at the first surface of the first layer, means for forming a second layer with second interlayer dielectric material over the self-alignment layer and the first layer, means for forming one or more holes through the second layer and the self-alignment layer to the portion of the one or more conductive structures at the first surface of the first layer, and means for replacing the first material of the self-alignment material that is in contact with the one or more holes with a second material that is different from the first material.

Example 22 includes the apparatus of Example 21, further comprising means for forming one or more conductive vias in the one or more holes.

Example 23 includes the apparatus of any of Examples 21 to 22, wherein replacing the first material further comprises means for removing the first material that is in contact with the one or more holes to form an airgap in the self-alignment layer, and means for utilizing air for the second material in the airgap in the self-alignment layer.

Example 24 includes the apparatus of any of Examples 21 to 22, wherein replacing the first material further comprises means for removing the first material that is in contact with the one or more holes to form an airgap in the self-alignment layer, and means for forming the second material in the airgap in the self-alignment layer.

Example 25 includes the apparatus of Example 24, further comprising means for forming non-conductive material on respective walls of the one or more holes.

Example 26 includes the apparatus of any of Examples 21 to 25, wherein the first material of the self-alignment layer comprises a low-k material and the second material of the self-alignment layer comprises a high-k material.

Example 27 includes the apparatus of any of Examples 21 to 26, wherein a first dielectric constant of the first material of the self-alignment layer is less than a second dielectric constant of the second material of the self-alignment layer.

Example 28 includes the apparatus of Example 27, wherein the first dielectric constant is 3.9 or lower.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An integrated circuit (IC) die, comprising:
a first layer with one or more conductive structures formed in a first interlayer dielectric material, with at least a portion of the one or more conductive structures at a first surface of the first layer;
a self-alignment layer in contact with non-conductive regions at the first surface of the first layer;
a second layer with second interlayer dielectric material in contact with the self-alignment layer and the portion of the one or more conductive structures at the first surface of the first layer; and
one or more conductive vias through the self-alignment layer and the second layer in respective contact with the portion of the one or more conductive structures at the first surface of the first layer,
wherein the self-alignment layer includes a first material where the self-alignment layer is in contact with the one or more conductive vias and a second material where the self-alignment layer is not in contact with the one or more conductive vias.

2. The IC die of claim 1, wherein the first material of the self-alignment layer comprises a low-k material and the second material of the self-alignment layer comprises a high-k material.

3. The IC die of claim 1, wherein a first dielectric constant of the first material of the self-alignment layer is less than a second dielectric constant of the second material of the self-alignment layer.

4. The IC die of claim 3, wherein the first dielectric constant is 3.9 or lower.

5. The IC die of claim 4, wherein the first material is air.

6. The IC die of claim 1, further comprising a non-conductive material in the second layer between respective walls of the second interlayer dielectric material and respective walls of the one or more conductive vias.

7. A system, comprising:
a substrate;
a power supply; and
an integrated circuit (IC) die attached to the substrate and coupled to the power supply, the IC die comprising:
a first layer with one or more conductive structures formed in a first interlayer dielectric material, with at least a portion of the one or more conductive structures at a first surface of the first layer;
a self-alignment layer in contact with non-conductive regions at the first surface of the first layer;
a second layer with second interlayer dielectric material in contact with the self-alignment layer and the portion of the one or more conductive structures at the first surface of the first layer; and
one or more conductive vias through the self-alignment layer and the second layer in respective contact with the portion of the one or more conductive structures at the first surface of the first layer, wherein the self-alignment layer includes a first material where the self-alignment layer is in contact with the one or more conductive vias and a second material where the self-alignment layer is not in contact with the one or more conductive vias.

8. The system of claim 7, wherein the first material of the self-alignment layer comprises a low-k material and the second material of the self-alignment layer comprises a high-k material.

9. The system of claim 7, wherein a first dielectric constant of the first material of the self-alignment layer is less than a second dielectric constant of the second material of the self-alignment layer.

10. The system of claim 9, wherein the first dielectric constant is 3.9 or lower.

11. The system of claim 10, wherein the first material is air.

12. The system of claim 7, further comprising a non-conductive material in the second layer between respective walls of the second interlayer dielectric material and respective walls of the one or more conductive vias.

13. A method, comprising:
receiving a substrate;
forming a first layer over the substrate with one or more conductive structures in a first interlayer dielectric material, with at least a portion of the one or more conductive structures at a first surface of the first layer;
forming a self-alignment layer of a first material over non-conductive regions at the first surface of the first layer;
forming a second layer with second interlayer dielectric material over the self-alignment layer and the first layer;
forming one or more holes through the second layer and the self-alignment layer to the portion of the one or more conductive structures at the first surface of the first layer; and
replacing the first material of the self-alignment material that is in contact with the one or more holes with a second material that is different from the first material.

14. The method of claim 13, further comprising:
forming one or more conductive vias in the one or more holes.

15. The method of claim 13, wherein replacing the first material further comprises:
removing the first material that is in contact with the one or more holes to form an airgap in the self-alignment layer; and
utilizing air for the second material in the airgap in the self-alignment layer.

16. The method of claim 13, wherein replacing the first material further comprises:
removing the first material that is in contact with the one or more holes to form an airgap in the self-alignment layer; and
forming the second material in the airgap in the self-alignment layer.

17. The method of claim 16, further comprising:
forming non-conductive material on respective walls of the one or more holes.

18. The method of claim 13, wherein the first material of the self-alignment layer comprises a low-k material and the second material of the self-alignment layer comprises a high-k material.

19. The method of claim 13, wherein a first dielectric constant of the first material of the self-alignment layer is less than a second dielectric constant of the second material of the self-alignment layer.

20. The method of claim 19, wherein the first dielectric constant is 3.9 or lower.
